(19) United States
(12) Patent Application Publication
(10) Pub. No.: US 2008/0017320 A1
(43) Pub. Date: Jan. 24, 2008

(54) SUBSTRATE PROCESSING APPARATUS

(76) Inventors: Ho-Geun Choi, Suwon-si (KR); Heung-Kyou Kang, Hwaseong-si (KR); Yong-Woo Kim, Hwaseong-si (KR); Pal-Kon Kim, Cheonan-si (KR)

Correspondence Address: F. CHAU & ASSOCIATES, LLC, 130 WOODBURY ROAD, WOODBURY, NY, 11797, US

(21) Appl. No.: 11/779,990

(22) Filed: Jul. 19, 2007

(30) Foreign Application Priority Data
Jul. 20, 2006 (KR) 10-2006-68074

(51) Int. Cl. H01L 21/306

(52) U.S. Cl. 156/345.54

(57) ABSTRACT

A substrate processing apparatus includes a process chamber, a fixed frame, a feed unit, and a supplying unit. A substrate is mounted to the fixed frame, the supplying unit is spaced apart from respective sides of the substrate to supply process fluid to the substrate, and the feed unit transports the fixed frame parallel to a longitudinal direction of the substrate. The process is automatically performed so that loss of the substrate is reduced and the substrate is effectively processed.

### CROSS-REFERENCE TO RELATED APPLICATION

This application claims priority to Korean Patent Application No. 2006-68074, filed on Jul. 20, 2006, the contents of which are herein incorporated by reference in their entirety.

### BACKGROUND OF THE INVENTION

1. Technical Field

The present disclosure relates to a substrate processing apparatus, and more particularly, to a substrate processing apparatus capable of performing various processes such as etching, drying, and cleansing of a substrate.

2. Discussion of the Related Art

Display devices include, for example, a liquid crystal display (LCD), a plasma display panel (POP), and an organic light emitting display (OLED). The display devices are used for electronic products such as a monitor of a large-sized TV, a laptop computer or a mobile telephone.

The display device includes a substrate. In order to manufacture a display device, various processes are performed on the substrate. Conventional processes on the substrate are performed manually by a worker. As a result, workability deteriorates and there is an increased risk of contaminating and damaging the substrate.

For example, an LCD using liquid crystal includes two sheets of transparent insulating substrates that are attached to and faced each other. An etching process that reduces the thickness of the attached substrates is performed. As the thickness of the substrate is reduced, the manual work of the worker becomes more difficult. Also, during the etching process, the substrate is not uniformly etched so that the quality of the LCD deteriorates.

### SUMMARY OF THE INVENTION

Embodiments of the present invention provide a substrate processing apparatus capable of effectively performing processes without damaging the substrate.

According to an embodiment of the present invention, the substrate processing apparatus includes a process chamber, a fixed frame, a feed unit, and a supplying unit. The process chamber accommodates the substrate, which is processed therein. The fixed frame supports respective sides of the substrate. The feed unit is located in the process chamber and contacts an end portion of the fixed frame to transport the fixed frame in a direction parallel to a longitudinal direction of the end portion. The supplying unit is spaced apart from the respective sides to supply a process fluid to the substrate. The process fluid may differ according to the process performed on the substrate. The process fluid may be at least one of an etchant to etch the substrate, a cleansing solution to clean the substrate, and a gas to dry the substrate.

The supplying unit includes a supplying pipe and a supplying member. The process fluid flows through the supplying pipe. The supplying member is connected to the supplying pipe to supply the process fluid to the substrate.

A substrate processing apparatus according to an embodiment of the present invention includes a substrate mounting unit, a process chamber, and a substrate detaching unit. The substrate mounting unit includes a fixed frame to support a substrate and mounts the substrate to the fixed frame. A process in performed on the substrate in the process chamber after the fixed frame is transported to the process chamber. The substrate detaching unit detaches the substrate on which the process has been performed from the fixed frame.

The process chamber includes a feed unit and a supplying unit. The feed unit is located in the process chamber and contacts an end portion of the fixed frame to transport the fixed frame parallel to a longitudinal direction of the end portion. The supplying unit is spaced apart from the respective sides of the substrate to supply the process fluid to the substrate.

The process chamber includes a first process chamber in which the substrate is etched, a second process chamber in which the substrate is cleaned, and a third process chamber in which the substrate is dried.

### BRIEF DESCRIPTION OF THE DRAWINGS

Embodiments of the present invention can be understood in more detail from the following detailed description when considered in conjunction with the accompanying drawings wherein:

FIG. 1 is a block diagram illustrating a substrate processing apparatus according to an embodiment of the present invention;

FIG. 2A is a plan view illustrating a substrate mounting unit of FIG. 1 according to an embodiment of the present invention;

FIG. 2B is a sectional view illustrating the fixed frame of FIG. 2A according to an embodiment of the present invention;

FIG. 3 is a view illustrating the operation of a first position converter of FIG. 1 according to an embodiment of the present invention;

FIG. 4 is a view illustrating the inside of a process chamber of FIG. 1 according to an embodiment of the present invention;

FIG. 5 is a view illustrating processes of oscillating a supply pipe of FIG. 4 according to an embodiment of the present invention;

FIG. 6A is a view illustrating an example of a spray method of supplying units of FIG. 4 according to an embodiment of the present invention;

FIGS. 6B to 6C are views illustrating spraying regions of the substrate of FIG. 6A, on which process fluid is sprayed;

FIG. 7 is a view illustrating the inside of a process chamber of FIG. 1 according to an embodiment of the present invention;

FIG. 8 is a perspective view illustrating a method of supplying the process fluid by slit nozzles of FIG. 7 according to an embodiment of the present invention;

FIG. 9A is a plan view illustrating the inside of the process chamber of FIG. 1 according to an embodiment of the present invention;

FIG. 9B is a perspective view illustrating supply units of FIG. 9A according to an embodiment of the present invention;

FIGS. 10A to 10C illustrate cross sections of the slit nozzles of FIG. 7 or 9A according to embodiments of the present invention;

FIG. 11 is a view illustrating the operation of a second position converter of FIG. 1 according to an embodiment of the present invention; and

FIG. 12 is a plan view illustrating a substrate detaching unit of FIG. 1 according to an embodiment of the present invention.

### DESCRIPTION OF EMBODIMENTS

Embodiments the present invention will be explained in more detail with reference to the accompanying drawings. This invention may, however, be embodied in many different forms and should not be construed as limited to the embodiments set forth herein. In the drawings, the same reference numerals may refer to same or similar components.

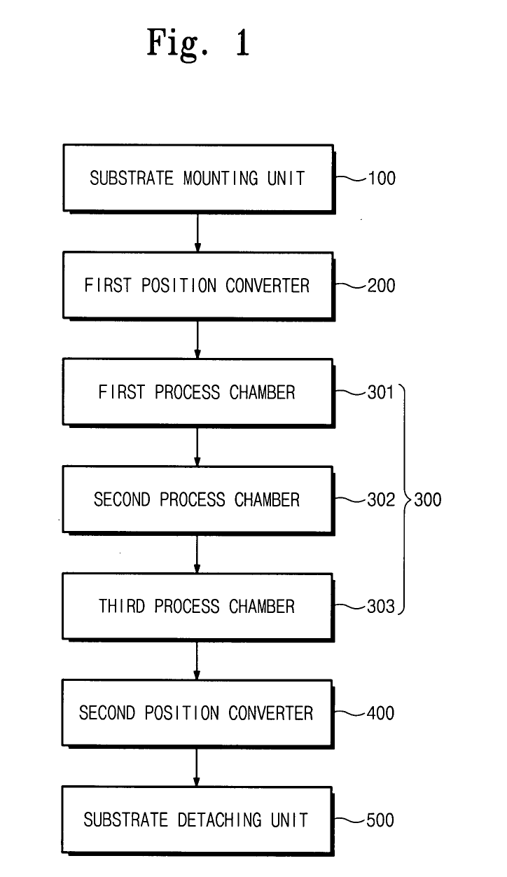

FIG. 1 is a block diagram illustrating a substrate processing apparatus according to an embodiment of the present invention.

Referring to FIG. 1 the substrate processing apparatus includes a substrate mounting unit 100, first and second position converters 200 and 400, a process chamber 300, and a substrate detaching unit 500. Various processes on a substrate are preformed in the process chamber 300. The process chamber 300 includes first to third process chambers 301, 302, and 303 that are classified according to processes performed therein. The substrate mounting unit 100 mounts the substrate to a fixing unit such that the substrate can be steadily fixed while the processes are performed. The substrate detaching unit 500 detaches the substrate from the fixing unit after the processes are completed. The first position converter 200 converts the position of the substrate to an appropriate position so that processes can be performed in the process chamber 300. The second position converter 400 converts the position of the substrate so that the substrate can be detached from the fixing unit.

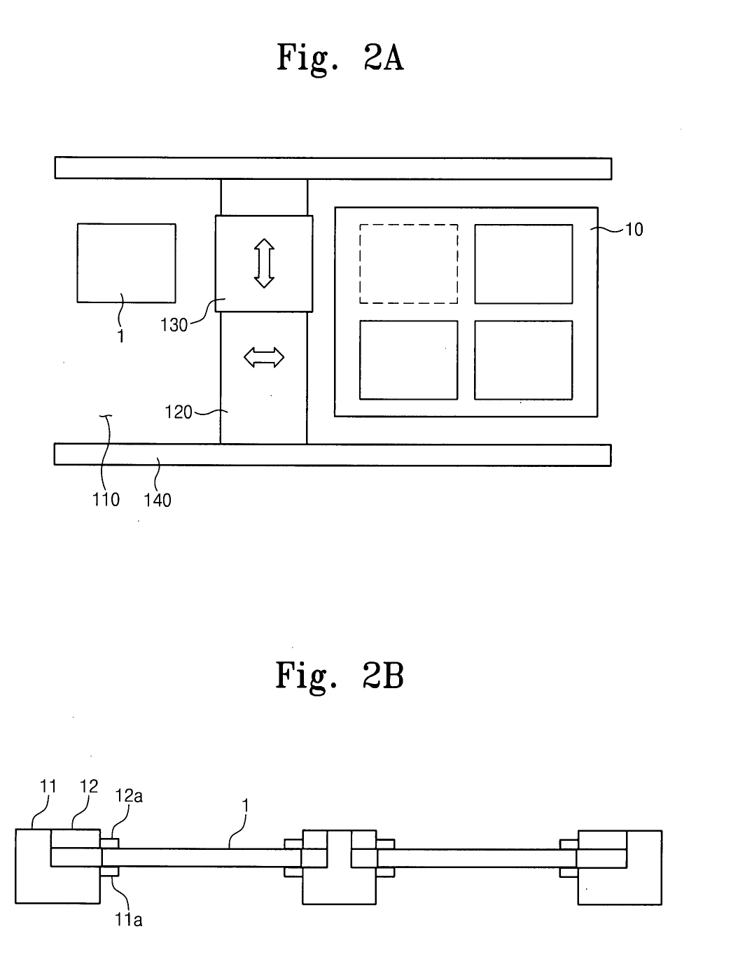

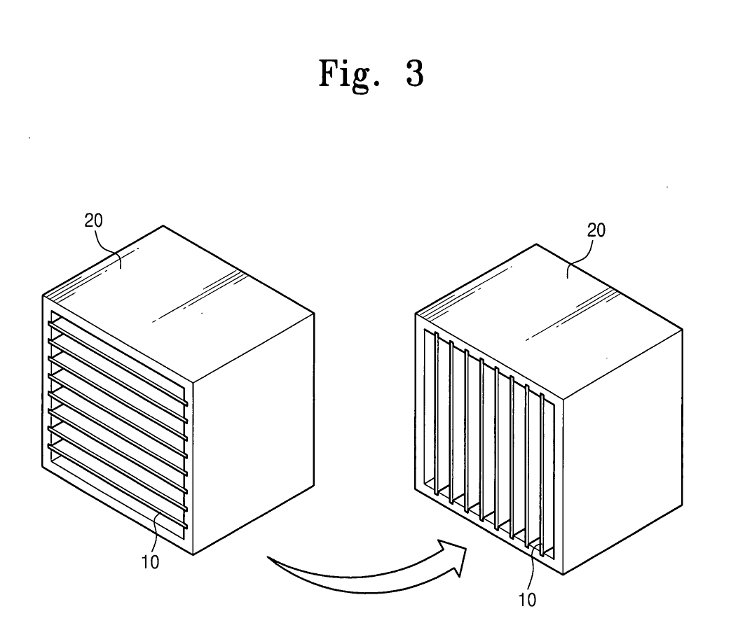

FIG. 2A is a plan view illustrating the substrate mounting unit of FIG. 1.

Referring to FIG. 2A, the substrate mounting unit includes a stage 110, a row directional position adjuster 120, a column directional position adjuster 130, and guide members 140. A substrate 1 to be processed and a fixed frame 10 are positioned on different sides of the stage 110. A pair of guide members 140 is formed in the row direction along the stage 110 and the row directional position adjuster 120 is guided between the pair of guide members 140 to move in the row direction. The column directional position adjuster 130 is formed on the surface of the row directional position adjuster 120, and is guided by the row directional position adjuster 120 to move in the column direction.

A plurality of substrates of the same size or of different sizes are mounted on the fixed frame 10. The row directional position adjuster 120 and the column directional position adjuster 130 move in the row direction and in the column direction, respectively, so that the substrate 1 is mounted in the position (indicated by a dotted line) that is empty in the fixed frame 10. An adsorption pad (not shown) may be provided on the surface of the column directional position adjuster 130 so that the substrate 1 is adsorbed. The row directional position adjuster 120 and the column directional position adjuster 130 are connected to a driving power source (not shown) so that the row directional position adjuster 120 and the column directional position adjuster 130 can move.

FIG. 2B is a sectional view illustrating the fixed frame of FIG. 2A.

Referring to FIG. 2B, the fixed frame 10 includes a first part 11 and a second part 12. The first part 11 has a bottom portion and a side portion that protrudes from the bottom portion so that an accommodating space is formed. The second part 12 has a bottom portion corresponding to the bottom portion of the first part 11. When the substrate 1 is placed in the first part 11 by the row directional position adjuster 120 and the column directional position adjuster 130, the second part 12 is received in the accommodating space and the substrate 1 is fixed between the first and second parts 11 and 12.

The first and second parts 11 and 12 have open regions corresponding to the substrate 1 such that the substrate 1 is exposed through the open regions. A process fluid reacts to the exposed portions of the substrate 1 such that various processes on the substrate 1 are performed. First and second supporters 11a and 12a are formed in the first and second parts 11 and 12 to support the substrate 1 during the processes. The first and second supporters 11a and 12a can have a minimum area so as not to disturb the reaction of the process fluid with the substrate 1. For example, the first and second supporters 11a and 12a may have a minute protrusion shape so that the first and second supporters 11a and 12a are in contact with a small area or a point of the substrate 1.

Magnetic members that face each other may be installed in the first and second parts 11 and 12. When an attraction caused by a magnetic force is applied between the first and second parts 11 and 12 by the magnetic members that face each other the substrate 1 can be more steadily fixed.

FIG. 3 is a view illustrating the operation of the first position converter of FIG. 1.

Referring to FIG. 3, the first position converter 200 includes a cassette 20 in which a plurality of fixed frames 10 are mounted. The cassette 20 has an open side through which the plurality of fixed frames are mounted in the cassette 20. The fixed frame 10 is transported in one direction, for example, in the horizontal direction. The fixed frames are mounted in the cassette 20 to be spaced apart from each other by a predetermined distance.

When the fixed frames are completely mounted in the cassette 20, the cassette 20 is rotated by a predetermined angle. For example, the cassette 20 is rotated by 90 degrees so that the fixed frames 10 are oriented in the vertical direction. At this time, the substrate 1 mounted in the fixed frame 10 rotates to be oriented in the vertical direction. The rotation of the cassette 20 is necessary to perform processes that require the substrate 1 to be oriented in the vertical direction. If the processes are performed in a state where the substrate 1 is horizontally laid, the first position converter 200 and the operation of rotating the cassette 20 may be omitted.

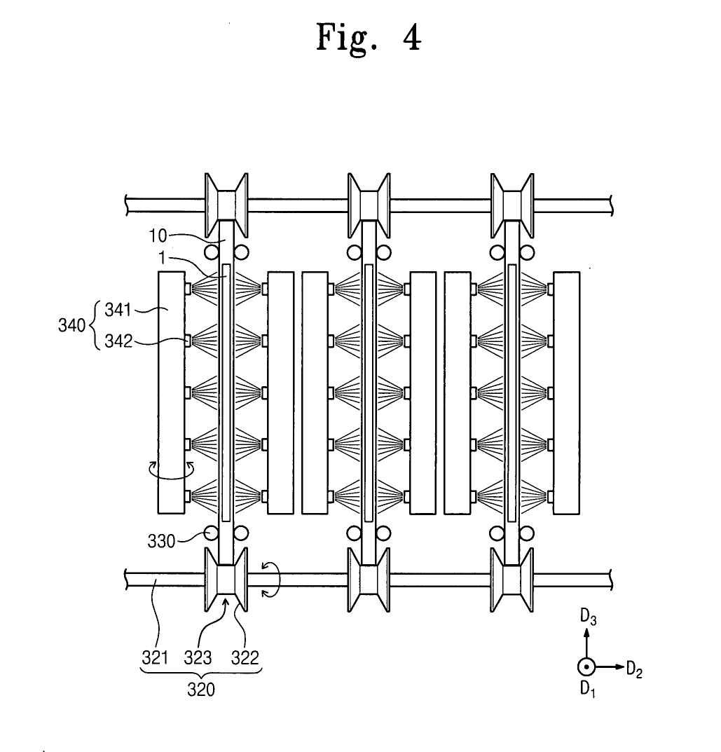

FIG. 4 is a view illustrating the inside of a process chamber of FIG. 1.

Referring to FIG. 4, the process chamber includes a feed unit 320 to feed the fixed frame 10 and supplying units 340 to supply process fluid to the substrate 1 mounted on the fixed frame 10. The feed unit 320 includes driving shafts 321 and rollers 322 through which the driving shafts 321 penetrate. A pair of the driving shafts 321 that face each other is installed along a second direction D₂ and spaced apart from each other by a predetermined distance in a third direction D₃. Although not illustrated in FIG. 4, a plurality of the pair of driving shafts 321 is also installed to be spaced apart from each other by a predetermined distance in a first direction D₁ (a direction coming out from the drawing).

The driving shafts 321 are rotated by a driving force and the rollers 322 rotate together with the driving shafts 321. The rollers 322 have a dumbbell shape, and include a central groove 323. The groove 323 corresponds to a width of the fixed frame 10 and the fixed frame 10 is inserted into the groove 323 and fed in the first direction D₁ when the rollers 322 rotate.

During the feeding, in order to prevent the fixed frame 10 from being titled and fallen down, supporting members 330 are installed to support both sides of the fixed frame 10. The supporting members 330 may have a variety of shapes. The supporting members 330 can contact the fixed frame 10 and slide when the fixed frames 10 are fed so that friction between the supporting members 330 and the fixed frame 10 is minimized. For example, the supporting members 330 may include rollers with wheels.

The supplying units 340 are disposed such that two neighboring supplying units 340 are interposed between the fixed frames 10 and face in opposite directions. The supplying units 340 include supplying pipes 341 and supplying members 342 connected to the supplying pipes 341. The supplying pipes 341 are elongated in a third direction D₃ and multiple supplying pipes 341 are disposed along the first and second directions D₁ and D₂. Alternatively, the supplying pipes 341 may be elongated in the first direction D₁ and multiple supplying pipes 341 may be disposed along the third direction D₃. The process fluid flows along the supplying pipes 341 and is supplied to respective sides of the substrate 1 mounted on the fixed frame 10 through the supplying members 342 (although FIG. 4 illustrates, for the sake of convenience, that the substrate 1 is mounted in sealed space in the fixed frame 10, the region corresponding to the substrate 1 is actually open as illustrated in FIG. 2B).

The first, second, and third directions D₁, D₂ and D₃ may be correspond to various directions in relation to the process chamber 300. For example, the third direction D₃ may be parallel or perpendicular to the bottom surface of the process chamber 300.

When the third direction D₃ is parallel to the bottom surface, the substrate 1 is oriented horizontally for feeding. In this case, the operation of rotating the fixed frame 10 by the first position converter 200 may be omitted.

When the third direction D₃ is perpendicular to the bottom surface, the substrate 1 is oriented vertically for feeding. In this case, an operation of rotating the substrate 1 by the first position converter 200 is necessary in order to vertically orient the substrate 1. When the substrate 1 is vertically oriented, the process fluid is uniformly sprayed from the respective both sides of the substrate 1 under the same gravitational force. Since the process fluid reaches the respective both sides of the substrate 1 and flows down along the surfaces of the substrate 1, the process fluid is can be collected and thus can be reused.

Each of the supplying members 342 includes a spraying nozzle with a spraying hole, and the process fluid is sprayed through the spraying nozzles and supplied to the substrate 1. The process fluid may vary according to type of the processes.

If a process is an etching process, the process fluid is an etchant. The etchant contacts the surfaces of the substrate 1 to cause chemical reaction and to reduce thicknesses of the substrate 1. For example, the substrate 1 is a glass substrate used in an LCD, and the etchant includes hydrofluoric acid liquid to react with silicon in the glass. In the LCD, the substrate 1 may be a single sheet or two sheets that are bonded to each other to face each other and have a liquid crystal layer formed therebetween.

If the process is a cleansing process, the process fluid is a cleansing solution. As the cleansing solution, de-ionized (DI) water may be used, and the DI water removes foreign matters from the surfaces of the substrate 1 by being sprayed onto the surfaces of the substrate 1.

If the process is a drying process, the process fluid is a gas. Air or inert nitrogen gas may be used as the gas and the gas is sprayed onto the surfaces of the substrate 1 to evaporate moisture from the surfaces of the substrate 1.

The etching, the cleansing, and the drying processes may be sequentially performed. For example, the etching may be performed in the first process chamber 301, the cleansing may be performed in the second process chamber 302, and the drying may be performed in the third process chamber 303.

The supplying members 342 spray the process fluid at a predetermined spraying angle. The supplying pipes 341 may oscillate within a predetermined angle range with respect to the third direction D₃ such that the process fluid can be supplied to wide areas of the substrate 1.

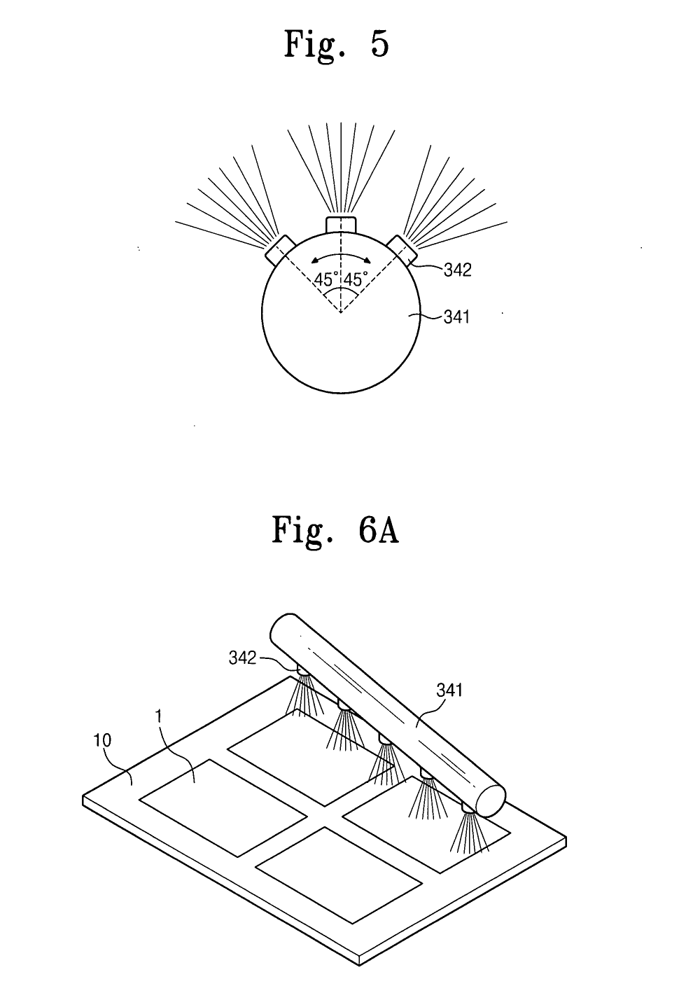

FIG. 5 is a view illustrating processes of oscillating a supply pipe of FIG. 4.

Referring to FIG. 5, the supplying pipes 341 oscillate with respect to predetermined reference axis. For example, the supplying pipes 341 may be oscillated from 45 degrees leftward to 45 degrees rightward with respect to a reference state in which the spraying nozzles face the substrate 1. Consequently, a spraying area of the spraying nozzle is extended. Since the supplying members 342 have a predetermined spraying angle, the spraying area is extended slightly greater than the oscillating range of the supplying pipes 341.

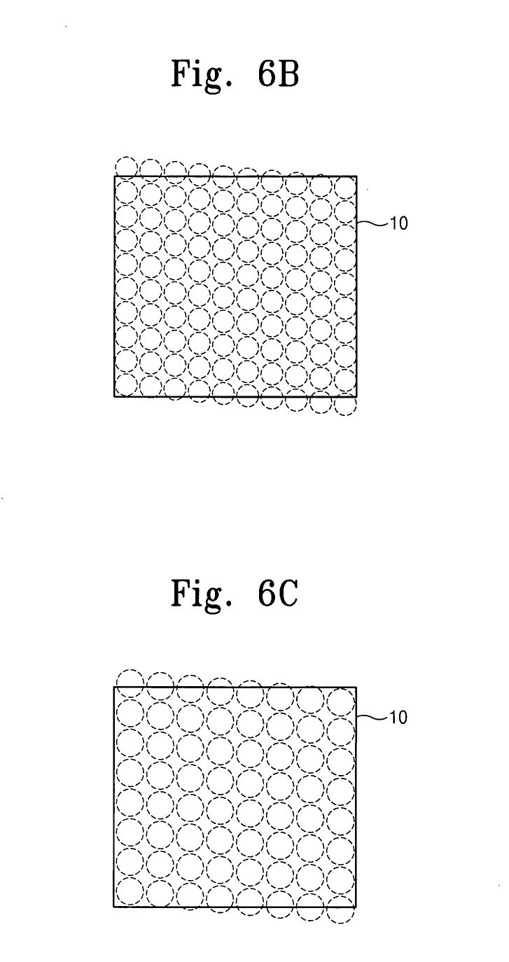

FIG. 6A is a view illustrating an example of a spray method of the supplying units of FIG. 4.

Referring to FIG. 6A, the supplying pipes 341 may tilted with respect to the fixed frame 10 at a predetermined angle. When the process fluid is an etchant, after the etchant chemically reacts with the surfaces of the substrate 1, a reaction byproduct such as sludge is generated and can be introduced into the spraying holes of the supplying members 342. The reaction byproduct blocks the spraying holes and interrupts the spraying of the etchant so that the etching can not be performed.

When the supplying pipes 341 are tilted, the introduced reaction byproduct is discharged through the supplying pipes 341 rather than blocking the spraying holes. The effect, obtained by tilting the supplying pipes 341, of discharging the reaction byproduct can be obtained when the substrate 1 is vertically oriented during the process. The tilting angle is about 3 degrees to about 10 degrees.

FIGS. 6B to 6C are views illustrating spraying regions of the substrate of FIG. 6A, on which process fluid is sprayed.

Referring to FIGS. 68 to 6C, the spraying regions of the fixed frame 10 on which the process fluid is sprayed by a single spraying nozzle are depicted by dotted circles. The circles arranged in the direction oblique to the fixed frames 10 represent the spraying nozzles formed in the same supplying pipes 341. The spraying regions on which the process fluid is sprayed by a single spraying nozzle differ according to spraying angles indicating a range in which the process fluid can be sprayed.

As the spraying angle is increased, the regions on which the process fluid is sprayed by a single nozzle are extended. FIG. 6B illustrates a spraying angle of 50 degrees and FIG. 6C illustrates a spraying angle of 75 degrees. The spraying angle is, for example, about 30 degrees to about 75 degrees.

The supplying units 340 can supply the process fluid to the substrate 1 not only in by spraying using the spraying nozzle, but also in the following methods.

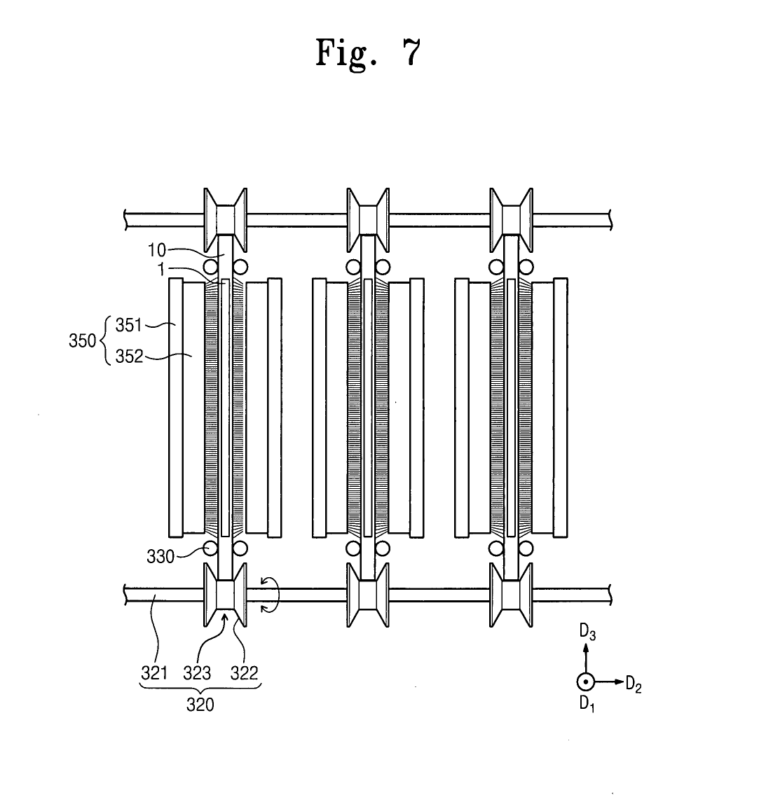

FIG. 7 is a view illustrating the inside of the process chamber of FIG. 1 according to an embodiment of the present invention.

Referring to FIG. 7, the process chamber 300 includes the feed unit 320 to feed the fixed frame 10 and supplying units 350 to supply the process fluid to the substrate 1 mounted in the fixed frame 10. The feed unit 320 includes driving shafts 321 and rollers 322. The process chamber 300 may further include supporting members 330 to support the fixed frame 10 while the fixed frame 10 is fed. The feed unit 320 and the supporting members 330 have the same structures as those described with reference to FIG. 4.

Each of the supplying units 350 includes a supplying pipe 351 and a supplying member 352. The supplying member 352 supplies the process fluid to the substrate 1 using a knife method. The supplying member 352 includes a slit nozzle distinguished from the above-described spraying nozzle. The slit nozzle includes first and second bodies that are spaced apart from each other, and the process fluid is discharged to the substrate from a space between the first and second bodies. In contrast to a point spraying method described in connection with the spraying nozzles, the slit nozzle employs a line discharging method, whereby the process fluid is uniformly supplied along a predetermined directional line.

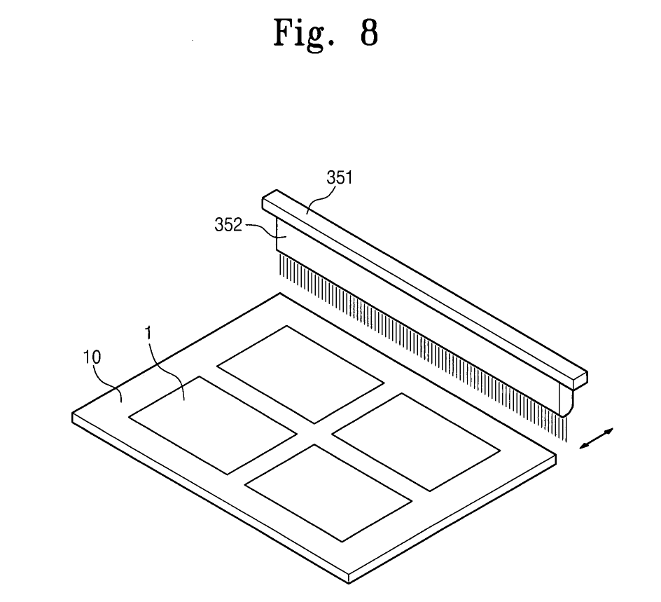

FIG. 8 is a perspective view illustrating a method of supplying the process fluid using the slit nozzle of FIG. 7.

Referring to FIG. 7, the supplying pipe 351 can be arranged parallel to or perpendicular to the fixed frame 10, when the slit nozzle is employed, portions through which the process fluid is discharged are connected to each other and are integrally formed. In this case, even when a certain region of the supplying member 352 is blocked by sludge, the process fluid supplied from other regions adjacent to the blocked region to the substrate 1 can compensate for the region having the blocked portion.

Since the process fluid is uniformly discharged from the supplying member 352 in a predetermined direction and is supplied to the substrate 1, the quantities of the process fluid applied to respective regions of the substrate 1 are uniform. For example, when the process fluid is the etchant, the etchant is applied to the respective regions of the substrate 1 so that overall regions of the substrate 1 can be etched to a uniform thickness.

In order to supply the process fluid to a wider region of the substrate 1 through a single supplying unit, the supplying units 350 may be moved. In the slit nozzle method, for example, the supplying pipe 351 moves linearly relative to the fixed frame 10 as indicated by an arrow in FIG. 8. The fixed frame 10 moves linearly with respect to the supplying pipe 351 or both the fixed frame 10 and the supplying pipe 351 may be simultaneously driven by a relative linear motion with respect to each other.

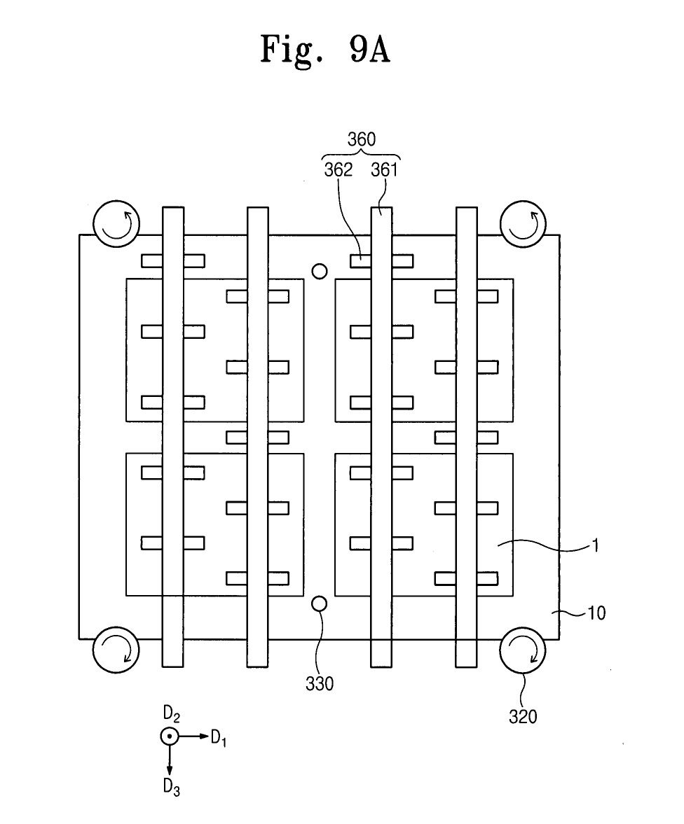

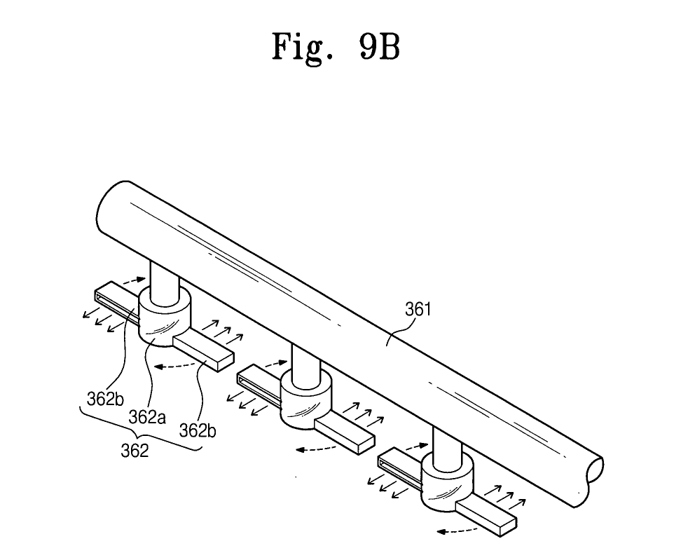

FIG. 9A is a plan view illustrating the inside of the process chamber of FIG. 1 according to an embodiment of the present invention.

Referring to FIG. 9A, the process chamber includes a feed unit 320 to feed the fixed frame 10, supplying units 360 to supply the process fluid to the substrate 1 mounted in the fixed frame 10, and supporting members 330 to support the fixed frame 10. The feed unit 320 and the supporting members 330 have the same structures as those described with reference to FIG. 4.

The supplying units 360 include supplying pipes 361 and supplying members 362 connected to the supplying pipes 361. The supplying members 362 supply the process fluid to the substrate 1 using the slit nozzle method.

FIG. 9B is a perspective view illustrating the supply units of FIG. 9A.

Referring to FIG. 9B, a plurality of lines 362a are branched from the supplying pipes 361 and the respective branched lines 362a are connected to respective pairs of symmetrical slit nozzles 362b. The respective pairs of the slit nozzles 362b rotate opposite to the direction in which the process fluid is discharged due to the force of the discharge of the process fluid. As above, since the pairs of the slit nozzles 362b rotate and discharge the process fluid, the process fluid can be provided on a wider region of the substrate 1. Moreover, as illustrated in FIG. 9A, since the pairs of the slit nozzles 362a are alternately arranged in the neighboring supplying pipes 361, the process fluid can be uniformly supplied to the overall regions of the substrate 1 without any region to which the process fluid is not supplied.

The spraying nozzle method and the slit nozzle method may be employed by the process chamber 300, individually or together. As mentioned above, it is possible that etching is performed in the first process chamber 301, cleansing is performed in the second process chamber 302, and drying is performed in the third process chamber 303. It is also possible that the spraying nozzles are used in etching and the slit nozzles are used in cleansing and drying.

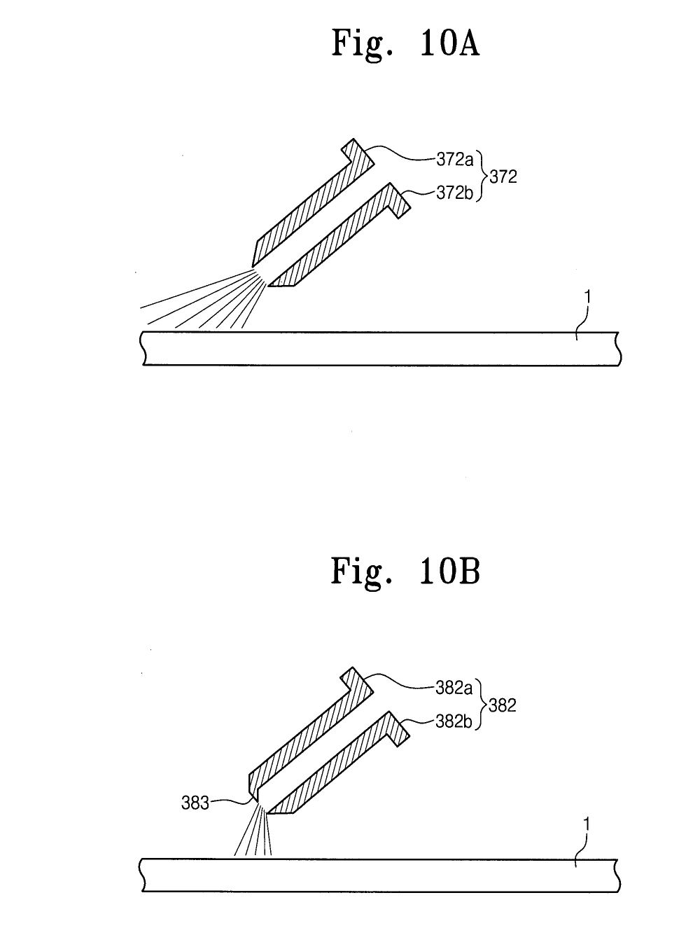

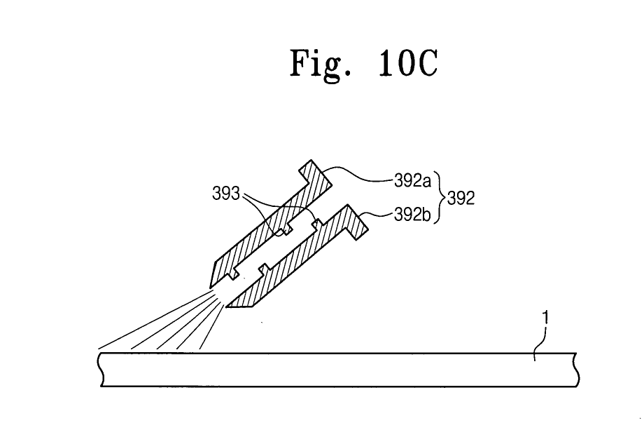

FIGS. 10A to 10C illustrate cross sections of the slit nozzles of FIG. 7 or 9A according to embodiments of the present invention.

Referring FIG. 10A, each of the slit nozzles 372 includes a first body 372a and a second body 372b spaced apart from each other to face each other. The first and second bodies 372a and 372b are symmetrical and the process fluid is discharged through an opening formed at ends of the first and second bodies 372a and 372b. As illustrated in FIG. 10A, the slit nozzles 372 can supply the process fluid, such that the openings of the nozzles are positioned oblique to the substrate 1 at a predetermined angle.

Referring FIG. 10B, each of slit nozzles 382 includes a first body 382a and a second body 382b spaced apart from each other to face each other. The first and second bodies 382a and 382b are symmetrical except with respect to a protrusion 383, and the process fluid is discharged through an opening formed at ends of the first and second bodies 382a and 382b.

The first body 382a includes the protrusion 383 protruded from the end thereof toward the opening. The protrusion 383 can adjust the direction in which the process fluid is supplied. For example, as illustrated in FIG. 10B, the process fluid is supplied in a direction toward a specific region of the substrate 1. The protrusion 83 can be when the process fluid is to be concentrated on a desired region of the substrate 1.

Although not limited to that illustrated in FIG. 10B, the asymmetrical structure is applied to the ends of the first and second bodies 382a and 382b so that the direction of supplying the process fluid can be adjusted.

Referring to FIG. 10C, each of slit nozzles 392 includes a first body 392a and a second body 392b spaced apart from each other to face each other and the process fluid is supplied through an opening formed at ends of the first and second bodies 392a and 392b.

Prominences 393 are formed at the ends of the first and second bodies 392a and 392b toward the space between the bodies 392a and 392b. At least one prominence 393 is formed in the first body 392a to be misaligned with a prominence 393 formed in the second body 392b. Since surfaces of the first and second bodies 392a and 392b are uneven due to the prominences 393, the flow of the process fluid is delayed. This can be applied to a case of preventing the substrate 1 from being damaged by strong discharge of the process fluid.

The shape of the prominences 393 is not limited to that depicted in FIG. 10C, In addition, the prominence(s) 393 may be formed in only one of the first and second bodies 392a and 392b. Alternatively, the prominences 393 may be formed in both first and second bodies 392a and 392b having shapes symmetric to each other.

The arrangement, the shape, and the number of the prominences 393 in the first and second bodies 392a and 392b can be adjusted in various ways, and thus the intensity of the discharge of the process fluid can be adjusted as desired in various ways.

In order to simultaneously adjust the discharge intensity of the process fluid and the regions to which the process fluid is supplied to the substrate 1, both the structure having the protrusions 383 and the structure having the prominences 393 may be employed.

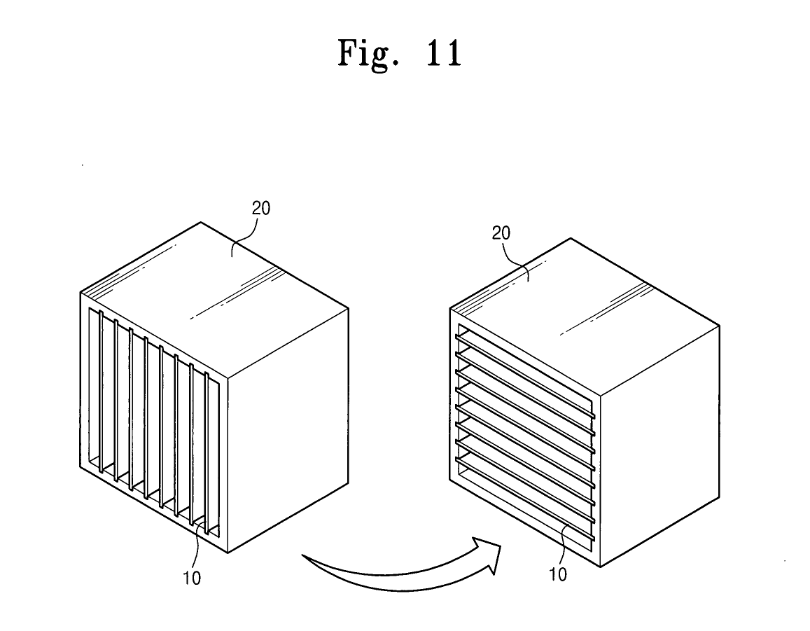

FIG. 11 is a view illustrating the operation of a second position converter of FIG. 1.

Referring to FIG. 11, the second position converter 400 includes a cassette 20 in which a plurality of fixed frames is mounted. Each of the fixed frames 10 includes the substrates, on which the processes are performed, mounted therein. The cassette 20 has an open side through which the plurality of fixed frames is mounted in the cassette 20. The fixed frame 10 is transported in one direction, for example, in the vertical direction and is rotated by 90 degrees toward the horizontal direction. Thus, the substrate 1 mounted in the fixed frame 10 rotates with the fixed frame 10. As a result, the operation of the first position converter 200 is reversed and the substrate 1 is horizontally oriented to be detached from the fixed frame 10. However, if the processes are performed while the substrate 1 is oriented horizontally in the process chamber 300, the second position converter 400 and the rotation operation associated with the second position converter 400 may be omitted.

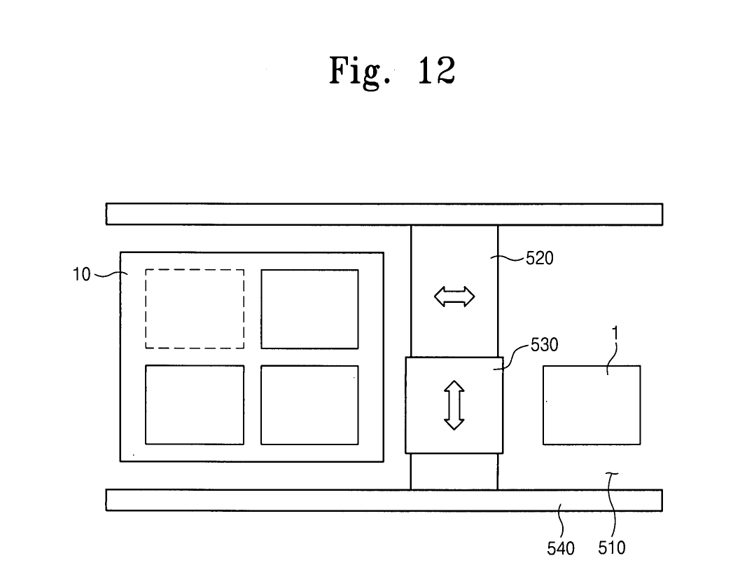

FIG. 12 is a plan view illustrating a substrate detaching unit of FIG. 1.

Referring to FIG. 12, the substrate detaching unit includes a stage 510, a row directional position adjuster 520, a column directional position adjuster 530, and guide members 540. The processed substrate 1 and a fixed frame 10 are positioned on lateral sides of the stage 510.

The fixed frame 10 has the same structure as illustrated in FIG. 2B. The row directional position adjuster 520 and the column directional position adjuster 530 respectively move in the row direction and in the column direction to detach the substrate 1. The substrates 1 are continuously detached from places on the fixed frame 10 except for an empty place (indicated by a dotted line) from which the substrate 1 has already been detached. All of the substrates are detached and the fixed frame 10 is transported to the substrate mounting unit 100.

In the above-mentioned operation, it is possible that the substrates are mounted in the fixed frames without a worker directly handling the substrates as the processes for the substrates are automatically performed. Thus, the substrates can be prevented from being damaged due to the lack of direct handling by the worker. Moreover, the etchant can be uniformly sprayed on the substrates using the spraying nozzle method or the slit nozzle method so that the substrates can be etched to a uniform thickness.

According to the embodiments of the present invention, loss on a substrate can be reduced and the processes for the substrates can be effectively performed.

Although the exemplary embodiments of the present invention have been described, it is to be understood that the present invention should not be limited to these exemplary embodiments but various changes and modifications can be made by one ordinary skilled in the art within the spirit and scope of the present invention as hereinafter claimed.

What is claimed is:

1. A substrate processing apparatus comprising:
a process chamber accommodating a substrate;
a fixed frame supporting the substrate;
a feed unit transporting the fixed frame in a direction parallel to a longitudinal direction of the end portion of the fixed frame, wherein the feed unit contacts an end portion of the fixed frame; and
a supplying unit spaced apart from the respective sides of the substrate to supply a process fluid to the substrate.

2. The substrate processing apparatus of claim 1, further comprising a supporting member supporting the fixed frame in a direction perpendicular to the respective sides.

3. The substrate processing apparatus of claim 1, wherein the fixed frame comprises:
a first part including a first bottom surface and a side surface perpendicular to the first bottom surface, wherein the first part includes an accommodating space; and
a second part including a second bottom surface corresponding to the first bottom surface and accommodated in the accommodating space.

4. The substrate processing apparatus of claim 3 wherein the feed unit comprises a roller having a groove corresponding to a width of the side surface.

5. The substrate processing apparatus of claim 1, wherein the process fluid comprises at least one of an etchant, a cleansing solution, and a gas.

6. The substrate processing apparatus of claim 1, wherein the respective sides are perpendicular to a bottom surface of the process chamber.

7. The substrate processing apparatus of claim 1 wherein the respective sides are parallel to a bottom surface of the process chamber.

8. The substrate processing apparatus of claim 1, wherein the supplying unit comprises:
a supplying pipe through which the process fluid flows; and
a supplying member connected to the supplying pipe to supply the process fluid to the substrate.

9. The substrate processing apparatus of claim 8, wherein the supplying pipe is disposed obliquely to a transporting direction of the fixed frame.

10. The substrate processing apparatus of claim 8, wherein the supplying pipe oscillates within a predetermined angle range.

11. The substrate processing apparatus of claim 8, wherein the supplying pipe moves linearly on a plane parallel to the respective sides.

12. The substrate processing apparatus of claim 8, wherein the supplying member comprises a plurality of spraying nozzles having spraying holes.

13. The substrate processing apparatus of claim 8 wherein the supplying member comprises at least one slit nozzle including first and second bodies that are spaced apart from each other, and the process fluid is discharged through a space between the first and second bodies.

14. The substrate processing apparatus of claim 13, wherein the slit nozzle comprises first and second slit nozzles symmetrically connected to a line branched from the supplying pipe, and the first and second slit nozzles rotate to supply the process fluid to the substrate.

15. The substrate processing apparatus of claim 13, wherein the slit nozzle comprises a prominence formed on at least one surface of the first and second bodies.

16. The substrate processing apparatus of claim 13, wherein the slit nozzle comprises a protrusion formed on at least one surface of and at an end of the first and second bodies.

17. A substrate processing apparatus comprising:
a substrate mounting unit including a fixed frame to support a substrate and mount the substrate to the fixed frame;
a process chamber to which the fixed frame is transported and in which a process for the substrate is performed; and
a substrate detaching unit to detach the substrate from the fixed frame, wherein
the process chamber comprises:
a feed unit contacting an end portion of the fixed frame to transport the fixed frame in a direction parallel to a longitudinal direction of the end portion; and
a supplying unit spaced apart from respective sides of the substrate to supply a process fluid to the substrate.

18. The substrate processing apparatus of claim 17, further comprising:
a first position converter to rotate the fixed frame by 90 degrees with respect to the transporting direction to a rotated position; and
a second position converter to rotate the fixed frame by 90 degrees from the rotated position.

19. The substrate processing apparatus of claim 17, wherein the process chamber comprises:
a first process chamber in which the substrate is etched;
a second process chamber in which the substrate is cleaned; and
a third process chamber in which the substrate is dried.
